(19) United States
(12) Patent Application Publication
(10) Pub. No.: US 2002/0031236 A1
(43) Pub. Date: Mar. 14, 2002

(54) Input apparatus, reproducing apparatus and volume adjusting method

(76) Inventors: Takayoshi Shimizu, Tokyo (JP); Takashi Kanai, Chiba (JP); Yukio Hiratsuka, Tokyo (JP)

Correspondence Address: COOPER & DUNHAM LLP, 1185 Avenue of the Americas, New York, NY, 10036, US

(21) Appl. No.: 09/909,387

(22) Filed: Jul. 19, 2001

(30) Foreign Application Priority Data
Jul. 21, 2000 (JP) P2000-220904
Jun. 21, 2001 (JP) P2001-187875

(51) Int. Cl. H03G 3/00

(52) U.S. Cl. 381/104

(57) ABSTRACT

According to the present invention, there are provided an input apparatus, a reproducing apparatus and a sound volume adjusting method in which a physical amount can be set to a desired physical amount by fine changing a physical amount slowly without user's mode switching operation after a physical amount had been coarsely changed to and reached near a desired physical amount at high speed by switching a coarse adjustment mode and a fine adjustment mode in which a physical amount is increased and decreased based on rotation speed of a control rotated by a user.

### BACKGROUND OF THE INVENTION

1. Field of the Invention

The present invention relates to an input apparatus in which a changing amount of a physical amount is changed in response to a rotational speed of a control rotated by a user, are producing apparatus for adjusting sound volume of reproduced sound by this input apparatus and a sound volume adjusting method.

2. Description of the Related Art

Heretofore, various audio output apparatus for amplifying an audio signal from an incorporated audio signal source or a connected audio signal source so as to drive a speaker have been developed This type of apparatus is referred to as an “audio amplifier apparatus” and output level for adjusting sound volume outputted from a connected speaker is adjusted by operating a volume adjustment operation section or by transmitting a volume adjustment command from a remote control apparatus.

As a sound volume adjustment apparatus for this kind of a conventional audio output apparatus, there is generally known a sound volume adjustment apparatus in which a user can adjust sound volume corresponding to a rotation amount by rotating an operation means comprised of a member called a “control”, for example. In this case, as a simplest arrangement, there may be considered an arrangement in which a rotary shaft of a control is directly coupled to a rotary shaft of a variable resistor referred to as a “so-called volume” and sound volume can be adjusted by change of its resistance value.

On the other hand, an audio output apparatus of a relatively high-class type is adapted to digitally adjust sound volume in which a rotation angle of a rotary control which is a rotary operation member is detected by a rotary encoder and sound volume set by a sound volume adjusting circuit incorporated within the audio output apparatus is changed stepwise in proportion to a detected rotation angle.

According to the conventional sound volume adjusting mechanism of the type constructed by a combination of a rotary control and a rotary encoder, it was very difficult to satisfactorily set the number of steps required when sound volume is changed stepwise. Specifically, when the sound volume adjusting mechanism is formed as the type constructed by a combination of a rotary control and a rotary encoder, if sound volume is changed by 1 dB step at every rotation of 15° as a predetermined angle of the rotary control such that sound volume can be adjusted by 97 steps ranging from 0 dB, −1 dB, −2 dB, . . . , −95 dB, −∞, then sound volume can be fine adjusted at every 1 dB step. However, in order to change sound volume from the minimum level to the maximum level, if one step is 15°, then the rotary control has to be rotated four times. As a result, it is unavoidable that it takes plenty of time to adjust sound volume.

In order to solve the above problem, there is already commercially available such a sound volume adjusting mechanism in which a sound volume changing characteristic called a volume curve, for example, is set to a predetermined curve, sound volume which changes by one step is decreased in a range of frequently-used sound volume and sound volume which changes by one step is increased in other ranges, thereby decreasing the number of steps from the minimum value to the maximum value of the sound volume.

With this arrangement, sound volume can be changed from the minimum level to the maximum level by rotating rotary control, for example, approximately one time. Thus, it becomes possible to rapidly adjust sound volume.

However, when the above volume curve is in use, if the volume curve is set uniquely, then it is frequently observed that users cannot set desired dB values, There arises a problem that sound volume cannot be fine adjusted.

### SUMMARY OF THE INVENTION

In view of the aforesaid aspect, it is an object of the present invention to provide an audio device of type capable of adjusting sound volume in which sound volume can rapidly be adjusted to desired level and in which sound volume can be fine adjusted at arbitrary level.

It is another object of the present invention to provide an input apparatus, a reproducing apparatus and a sound volume adjusting method in which sound volume can rapidly be adjusted to desired level and in which sound volume can be fine adjusted at arbitrary level.

According to an aspect of the present invention, there is provided an input apparatus for outputting a physical amount based on rotation operation done by a user This input apparatus is comprised of a rotary operation means rotated by operation of a user and outputting a rotation signal each time it is rotated a predetermined rotation angle, a speed detecting means for detecting a rotation speed of the rotary operation means based on a rotation signal outputted from the rotary operation means and a control means for changing a changing amount of an outputted physical amount based on the detected rotation speed.

According to another aspect of the present invention, there is provided a reproducing apparatus for adjusting reproduction volume by switching a coarse adjustment mode and a fine adjustment based on rotation of a control operated by a user and whose rotation angle is not restricted. This reproducing apparatus is comprised of a reproducing means for reproducing an audio signal, an attenuating means for adjusting reproduction volume of the audio signal, an amplifying means for amplifying an audio signal whose level was adjusted by the attenuating means, a rotation detecting means coupled to a control operated by a user and which outputs a predetermined rotation signal each time it is rotated a predetermined rotation angle, a speed detecting means for detecting rotation speed of the control based on a rotation signal outputted from the rotation detecting means, a direction detecting means for detecting rotation direction of the control based on a rotation signal outputted from the rotation detecting means, an adjustment amount output means for outputting a first adjustment amount for changing the reproduction sound volume by the first adjustment amount in the fine adjustment mode, a memory means for storing therein control information for changing the reproduction volume by a second adjustment amount in a coarse adjustment mode and a control means for controlling the attenuating means such that the attenuating means increases or decreases the reproduction sound volume in the fine adjustment mode based on the first adjusted amount outputted from the adjustment amount output means and detected result of the direction detecting means when it is detected by the speed detecting means that the control is operated at first speed and controlling the attenuating means such that the attenuating means increases or decreases the reproduction sound volume in the coarse adjustment mode based on the second adjustment amount controlled by control information stored in the memory means and detected result of the direction detecting means when it is detected by the speed detecting means that the control is operated at second speed.

In accordance with a further aspect of the present invention, there is provided a sound volume adjusting method for adjusting reproduction sound volume by switching a coarse adjustment mode and a fine adjustment mode based on rotation of a control operated by a user and whose rotation angle is not restricted. This sound volume adjusting method is comprised of the steps of detecting rotation speed and rotation direction of the control, comparing the rotation speed with a predetermined speed, adjusting the reproduction sound volume based on a first adjustment amount and the detected rotation direction in a fine adjustment mode if it is determined based on the comparison that rotation of the control is lower than a predetermined speed and adjusting the reproduction sound volume based on a second adjustment amount and the detected rotation direction in a coarse adjustment mode if it is determined by the comparison that rotation of the control exceeds a predetermined speed

### BRIEF DESCRIPTION OF THE DRAWINGS

FIG. 1 is a block diagram showing an example of an overall arrangement of an apparatus according to an embodiment of the present invention;

FIG. 2 is a block diagram showing an example of an arrangement of volume control of an apparatus according to an embodiment of the present invention;

FIG. 3A is an explanatory diagram showing examples in which volume values change from −∞ to −64 of examples in which step values are corresponding to volume values in each volume control mode according to an embodiment of the present invention;

FIG. 3B is an explanatory diagram showing examples in which volume values change from −63 to −31 of examples in which steps values are corresponding to volume values in each volume control mode according to an embodiment of the present invention;

FIG. 3C is an explanatory diagram showing examples in which volume values change from −30 to 0 of examples in which step values are corresponding to volume values in each volume control mode according to an embodiment of the present invention;

FIG. 4 is an explanatory diagram showing an example of volume curve characteristics according to an embodiment of the present invention;

FIG. 5 is a flowchart to which reference will be made in explaining the manner in which tables are selected according to an embodiment of the present invention;

FIG. 6 is a flowchart to which reference will be made in explaining the manner in which data are changed based on pulse speeds;

FIG. 7 is an explanatory diagram showing examples of state transitions of changing modes according to an embodiment of the present invention;

FIG. 8 is an explanatory diagram showing examples in which data are changed when tables are switched according to an embodiment of the present invention; and

FIG. 9 is an explanatory diagram showing an example of a relationship between a pulse output and a mode according to an embodiment of the present invention.

### DESCRIPTION OF THE PREFERRED EMBODIMENT

An input apparatus, a reproducing apparatus and a sound volume adjusting method according to an embodiment of the present invention will be described below with reference to the accompanying drawings.

In this embodiment, the present invention is applied to an audio amplifying apparatus assembled into a stereo reproducing apparatus, In particular, in the case of this embodiment, the present invention is applied to a device called a receiver apparatus which is integrally formed as one body of an audio tuner.

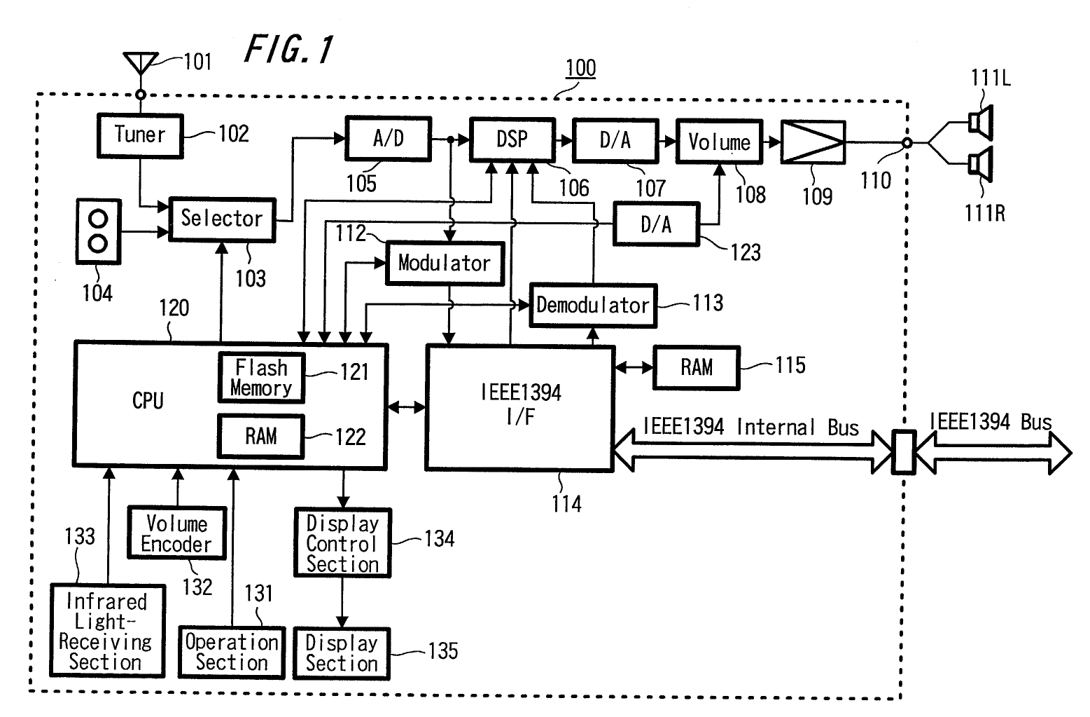

FIG. 1 is a block diagram showing an example of an arrangement of a receiver apparatus according to an embodiment of the present invention In FIG. 1, reference numeral 100 generally depicts a receiver apparatus. As shown in FIG. 1, an antenna 101 is connected to the receiver apparatus 100 and radio broadcasting of an arbitrary frequency can be received by a tuner 102 within the receiver apparatus 100. An audio signal received at and outputted from the tuner 102 is supplied to a selector 103. The receiver apparatus 100 according to this embodiment includes an analog audio input terminal 104, and an analog audio signal obtained at this analog audio input terminal 104 is supplied to the selector 103 The selector 103 selects any one of audio signals and outputs a selected audio signal under control of a system controller 120 of this receiver apparatus 100. Selection in this selector 103 is equivalent to selection of an input audio signal source. The receiver apparatus 100 according to this embodiment can be connected an IEEE (The Institute of Electrical and Electronic Engineers) 1394 bus line which is a digital serial communication bus so that the receiver apparatus 100 can also select inputted audio data transmitted through this IEEE 1394 bus line. An arrangement to which this IEEE 1394 bus line is connected will be described later on.

An audio signal selected by the selector 103 is supplied to an analog-to-digital(A/D) converter 105, in which it is converted to digital audio data The digital audio data converted by the A/D converter 105 is supplied to a digital signal processor (DSP) 106, in which it is processed in a suitable audio processing manner such as tone control and reverberation The processing state at this DSP 106 is set by a command from the system controller 120.

The digital audio data processed by the DSP 106 is supplied to a digital-to-analog (D/A) converter 107, in which it is converted into 2-channel analog audio signals. The analog audio signal thus converted is supplied to a volume circuit 108, in which it is controlled in sound volume. Sound volume control in this volume circuit 108 is executed based on a signal which results from converting control data supplied from the system controller 120 by a D/A converter 123 This sound volume control will be described in detail later on.

The audio signal whose sound volume was adjusted by the volume circuit 108 is supplied to an amplifying circuit 109, in which it is amplified to an output which can drive speakers The audio signal thus amplified is supplied to a speaker terminal 110, and sounds are emanated from speaker apparatus 111L, 111R connected to this speaker terminal 110. While two left-channel and right-channel speaker apparatus 111L, 111R are connected to the speaker terminal 110 as described above, the present invention is not limited thereto, and speaker apparatus of other channel arrangement may be connected to the speaker terminal 110. While a signal processing block of only one system has been described so far in FIG. 1 for simplicity of description, the present invention is not limited thereto, and there may be provided a plurality of respective section in accordance with the number of output channels.

This receiver apparatus 100 has a function to be connected to a bus line prescribed by the IEEE (The Institute of Electrical and Electronics Engineers) 1394 system. Therefore, the receiver apparatus 100 includes a bus line interface section 114. Then, the digital audio data selected by the selector 103 and outputted from the A/D converter 105 is modulated in bus line transmission by a modulating circuit 112 and supplied to the interface section 114, in which it is converted into data of a format prescribed by the IEEE 1394 system so that it can be transmitted to other device by a connected bus line. Audio data contained in data received by the interface section 114 through the bus line is decoded by a demodulating circuit 113 and the audio data thus decoded is supplied to the DSP 106 and thereby outputted. A random-access memory (RAM) 115 is connected to the interface section 114.

The IEEE 1394 bus line has the arrangement in which not only stream data such as audio data but also various control commands and their responses can be transmitted. The commands and the responses generated by the system controller 120 can be transmitted from the interface section 114 to the bus line, and the commands and the responses received by the interface section 114 from the bus line side are supplied to the system controller 120 Accordingly, the system controller 120 can judge the commands and the responses thus supplied As the transmission of the commands and the responses through the IEEE 1394 bus line, there can be applied such one which is prescribed by an AV/C command, for example With application of this AV/C command, the receiver apparatus 100 can be connected to other audio devices such as a disk reproducing apparatus and a recording and reproducing apparatus and thereby combined with an audio reproducing system, whereby the system controller 120 within the receiver apparatus 100 can control devices within the system in a centralized fashion.

The system controller 120 is a processing section which can function as a central control unit, i.e. CPU (central processing unit) which controls operations of respective sections of this receiver apparatus 100, The CPU 120 incorporates therein a flash memory 121 in which there are stored various programs and setting data and a random-access memory (RAM) 122 which is used in calculation processing. Data concerning sound volume control, which will be described later on, is also stored in the flash memory 121.

This receiver apparatus 100 includes an operation section 131 comprised of various operation keys and a volume encoder section 132 for adjusting sound volume. The system controller 120 judges these operations and sets a corresponding operation When an infrared signal from a remote control apparatus, not shown, is received at an infrared light-receiving section 133, the system controller 120 executes an operation corresponding to a command thus received. The volume encoder 132 is comprised of a rotary operation control and circuit assemblies for detecting rotation of such rotary operation control. When a user rotates the operation control of this volume encoder 132 section, sound volume of the audio signal outputted from the speaker apparatus connected to the speaker terminal 100 can be adjusted. Various keys comprising the operation section 131 and the rotary operation control of the volume encoder section 132 are disposed on the front panel of the apparatus, for example.

Further, a display control section 134 is connected to the system controller 120, and a display section 135 can display data and images under control of this display control section 134. The display section 135 is comprised of a fluorescent display tube disposed on the front panel of the apparatus, for example, and is able to display operation situations of this receiver apparatus 100 (or operation situations of other apparatus connected to this receiver apparatus 100 through the bus line) in a suitable form such as characters, figures and numerals.

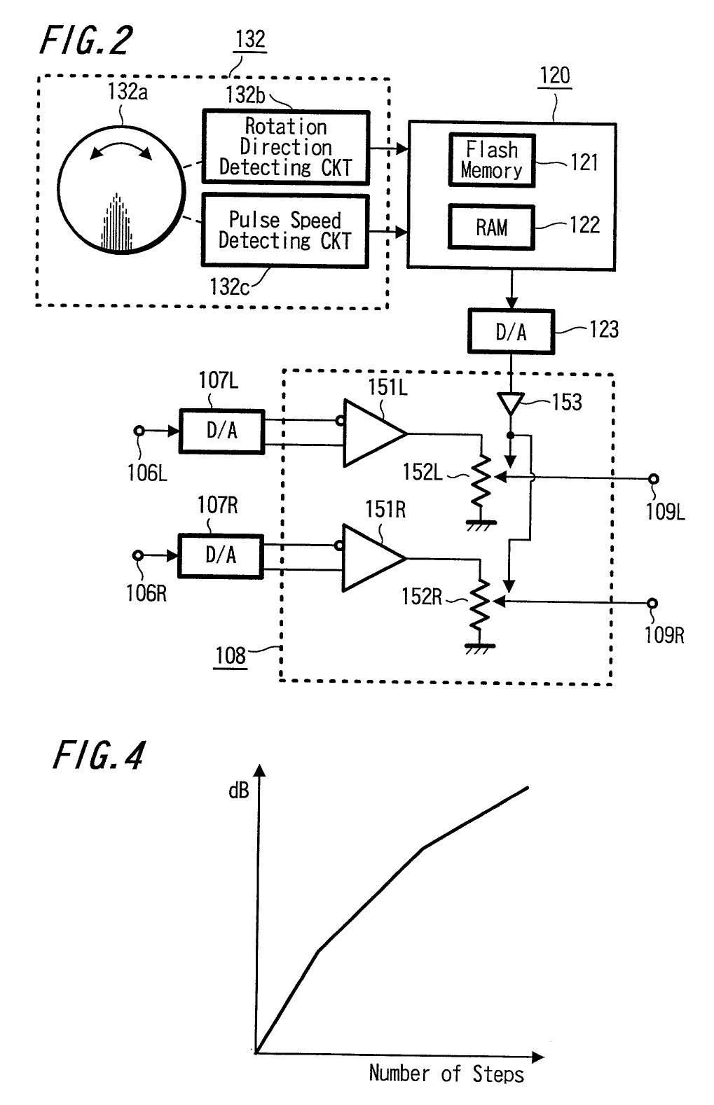

Processing and arrangement concerning the sound volume adjustment done by the receiver apparatus 100 according to this embodiment will be described with reference to FIG. 2. As shown in FIG. 2, the volume encoder section 132 includes a rotary control 132a which can freely be rotated by users in the clockwise direction and in the counter-clockwise direction and incorporates therein an encoder for outputting a pulse signal at every constant angle of rotation of the rotary control 132a. This encoder is adapted to output one pulse signal each time the rotary control 132a is rotated 15°.

Then, when the rotary control 132a is rotated, its rotation direction is detected by a rotation direction detecting circuit 132b and its rotation speed is detected by a pulse speed detecting circuit 132c. The pulse speed detecting circuit 132c detects a period of a pulse signal outputted from the rotary control 132a. Detected outputs from the two detecting circuits 132b, 132c are supplied to the system controller 120.

The system controller 120 judges the rotation state of the rotary control 132a, i.e., operated state of user based on the detected outputs from the two detecting circuits 132b, 132c and generates control for sound volume adjustment based on the judged result. This control data is converted into an analog voltage signal by the D/A converter 123 and the analog signal is supplied to the volume circuit 108, whereby sound volume can be set to sound volume indicated by control data. Sound volume is controlled by the system controller 120 stepwise (in a stepwise fashion). Data concerning setting of steps are stored in the flash memory 121 within the system controller 120

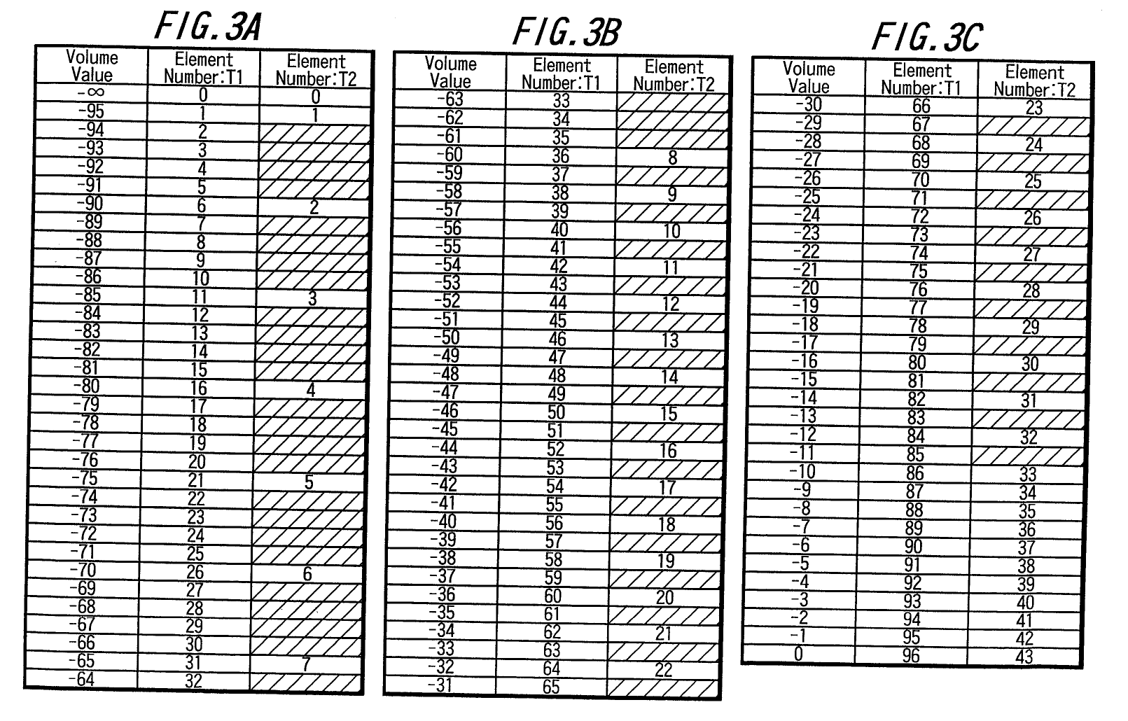

FIGS. 3A, 3B and 3C are respectively diagrams showing examples of corresponding data of step values and volume values stored in this flash memory 121. In the case of this embodiment, there are prepared two modes of a first sound volume adjustment mode and a second sound volume adjustment mode. Element numbers T1 show corresponding data of the number of steps and volume values in the first sound volume adjustment mode. Element numbers T2 show corresponding data of the number of steps and volume values in the second sound volume adjustment mode. The first sound volume adjustment mode is a mode in which sound volume can be fine adjusted at every constant value by one step. The second sound volume adjustment mode is a mode in which sound volume can be adjusted based on a previously-set volume curve.

The first sound volume adjustment mode is a mode in which sound volume can be adjusted at the unit of 0 dB to 1 dB by 97 steps of −1 dB, −2 dB, . . . , −95 dB, −∞. In the step values of the element numbers T1 corresponding to the first sound volume adjustment mode in FIGS. 3A, 3B and 3C, −∞ which is the minimum level is set to a step value 0 and set to step values 1, 2, . . . each time sound volume is decreased from −85 dB by 1 dB. At 0 dB which is the maximum level, a step value is set to 96, In this case, 1 dB of the adjustment step is adjusted as the minimum resolution of the volume value.

In the case of the second sound volume adjustment mode, steps are set at the unit of 1 dB from 0 dB to −10 dB, steps are set at the unit of 2 dB from −10 dB to −60 dB, and steps are set at the unit of 5 dB from −60 dB to −95 dB. The next step of −95 dB becomes −∞ which is the minimum level. In the step values of the element numbers T2 corresponding to the second sound volume adjustment mode in FIGS. 3A, 3B and 3C, −∞ which is the minimum level is set to a step value 0, −95 dB is set to a step value 1 and 0 dB which is the maximum level is set to a step value 43.

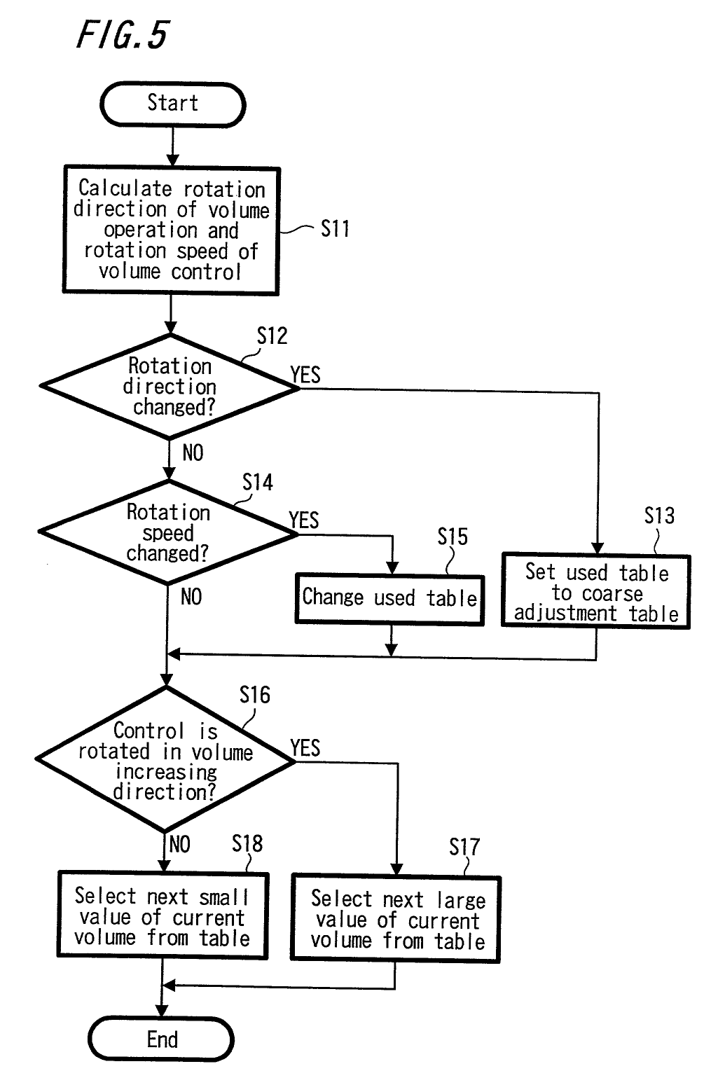

FIG. 4 shows the state of a volume curve set by this second sound volume adjustment mode. In FIG. 4, a horizontal axis represents the number of steps and a vertical axis represents dB values. Since the number of steps and dB values in FIG. 4 are made corresponding to the number of steps and volume values of FIGS. 3A, 3B, 3C, the upper left portion of the characteristic curve represents the sound volume of the minimum level and the lower left portion of the characteristic curve represents the sound volume of the maximum level. Accordingly, the changing characteristic is changed in three stages.

Referring back to FIG. 2, by using the corresponding data of the step values and the volume values, a volume value which is a value of sound volume is calculated based on the rotating situation of the volume encoder section 132 within the system controller 120. The volume value thus calculated is outputted to the D/A converter 123 as sound volume control data. The volume value thus calculated is stored in a predetermined area of the RAM 122 within the system controller 120.

Sound volume control data outputted from the system controller 120 is converted into an analog voltage value by the D/A converter 123, and this voltage value signal is supplied to the control terminal of the volume circuit 108. The volume circuit 108 set a volume value of an audio signal corresponding to the supplied voltage signal.

The volume circuit and an arrangement of its front stage will be described. In the case of this embodiment, since the two left- and right-channel signals are used as the audio signals, a left-channel D/A converter 107L an a right-channel D/A converter 107R are prepared as D/A converters and thereby a left-channel output 106L and a right-channel output 106R of the DSP 106 are converted into analog signals of respective channels.

Since the D/A converters 107L, 107R are adapted to output analog signals as differential signals, the differential signals are supplied to differential amplifiers 151L, 151R and thereby outputted as a signal of one system at every channel in the volume circuit 108. Outputs from the differential amplifiers 151L, 151R of respective channels are supplied to variable resistors 152L, 152R prepared at every channel. The variable resistors 152L, 152R of the respective channels adjust levels of the signals based on the voltage value of the sound volume control signal. The signals thus adjusted in level are supplied to input terminals 109L, 109R of the amplifier 109 at every channel. The analog sound volume control signal thus converted by the D/A converter 123 is supplied through a buffer amplifier 153 to the two variable resistors 152L, 152R, and the same volume value is set to the variable resistors 152L, 152R of the respective channels.

The manner in which the volume value is set based on the operation situation of the volume encoder section 132 within the system controller 120 will be described with reference to a flowchart of FIG. 5

Referring to FIG. 5and following the start of operation, control goes to a step S11, whereat the system controller 120 calculates a rotation direction and a rotation speed of the rotary control 132a of the volume encoder section 132 based on data supplied from the volume encoder section 132. It is determined at the next decision step S12 by the system controller 120 based on the calculated result whether or not the rotation direction is changed. If the rotation direction is changed from the immediately-preceding rotation direction as represented by a YES at the decision step S12, then control goes to a step S13, whereat the first sound volume adjustment mode, i.e., fine adjustment table T1 is set from the corresponding tables T1, T2 shown in FIG. 3.

If the rotation direction is not changed as represented by a NO at the decision step S12, then control goes to the next decision step S14. It is determined at the decision step S14 whether or not the rotation speed is changed so as to satisfy predetermined conditions. Details of predetermined conditions by which it can be determined that the rotation speed is changed will be described later on. If the rotation speed is changed as represented by a YES at the decision step S14, then control goes to a step S15, whereat the used table is changed to a table of a different mode. Specifically, when the first sound volume adjustment mode is set, the table is changed to the second sound volume adjustment mode. When the second sound volume adjustment mode table is set, the second sound volume adjustment mode table is changed to the first sound volume adjustment mode table.

When the used table is changed to the fine adjustment mode table at the step S13, if it is determined at the decision step S14 that the rotation speed is changed and when the mode of the used table is changed at the step S15, control goes to the next decision step S16. It is determined at the decision step S16 by the system controller 120 whether or not the rotation direction is the sound volume increasing direction. If the rotation direction is the sound volume increasing direction as represented by a YES at the decision step S16, then control goes to a step S17, whereat a volume value which is incremented by one step in the direction in which the sound volume is increased in the used table from the current volume value each time the pulse detecting circuit 132c within the volume encoder section 132 detects one pulse. Then, sound volume control data corresponding to the selected volume value is outputted.

If the rotation direction is not the direction in which the sound volume is increased, i.e., the rotation direction is the direction in which the sound volume is decreased as represented by a NO at the decision step S16, then control goes to a step S18, a volume value incremented by one step in the direction in which the sound volume is decreased in the used table from the current volume value each time the pulse detecting circuit 132c within the volume encoder section 132 detects one pulse. Then, the sound volume control data corresponding to the selected volume value is outputted.

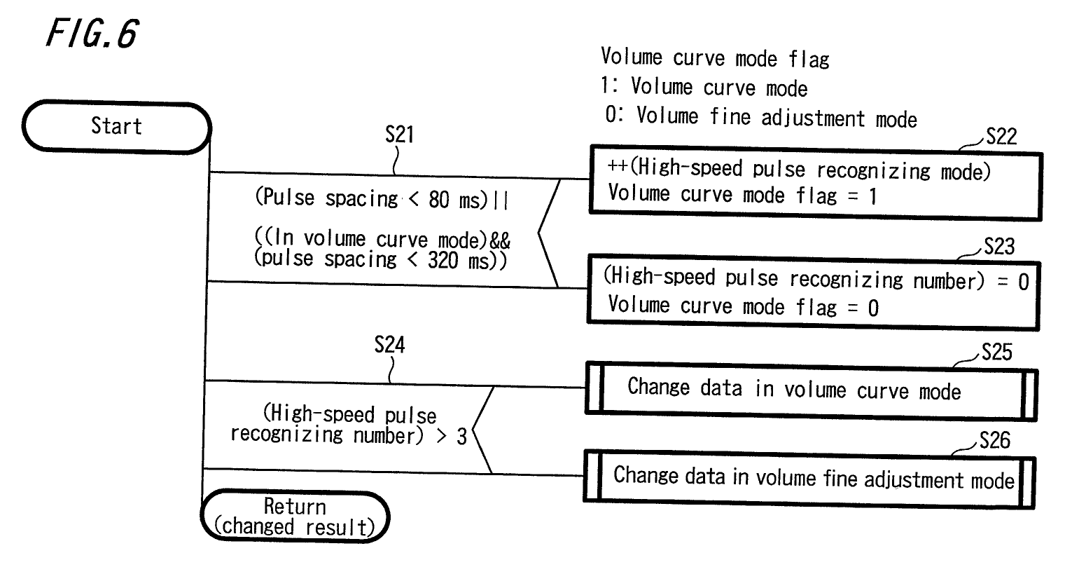

Volume values are set in this manner. Details of the processing in which it is determined at the decision step S14 that the rotation speed is changed will be described with reference to a flowchart of FIG. 6.

Referring to FIG. 6 and the following the start of operation, it is determined at a decision step S21 whether or not the pulse spacing detected by the pulse detecting circuit 132c is less than 80 ms. Simultaneously, when the volume curve mode is set, it is determined whether or not the pulse spacing is less than 320 ms. Specifically, an inequality of (pulse spacing <80 ms) or ((volume curve mode) and (pulse spacing <320 ms)) is evaluated.

Then, if it is determined at the decision step S21 that the pulse spacing is less than 80 ms, control goes to a step S22, whereat the value of the high-speedpulse recognizing number is incremented and a volume curve mode flag is set to “1” If it is determined at the decision step S21 that the pulse spacing is not less than 80 ms, control goes to a step S23, whereat the value of the high-speed pulse recognizing number is set to 0 and the volume curve mode flag is set to “0”.

After the steps S22 and S23 had been executed, it is determined at a decision step S24 whether or not the value of the high-speed pulse recognizing number exceeds 2. If it is determined at the decision step S24 that the high-speed pulse recognizing number is over 2, then control goes to a step S25, whereat there is set the mode in which data of volume value is changed in the volume curve mode, i.e., the second sound volume adjustment mode. If it is determined at the decision step S24 that the number of the high-speed pulse recognizing number is not over 2, then control goes to a step S26, whereat there is set the mode in which data of the volume value is changed in the fine adjustment mode, i.e., the first sound volume adjustment mode.

If it is determined at the decision step S21 that the pulse spacing is less than 320 ms while the volume curve mode is being set, then the volume curve mode is maintained.

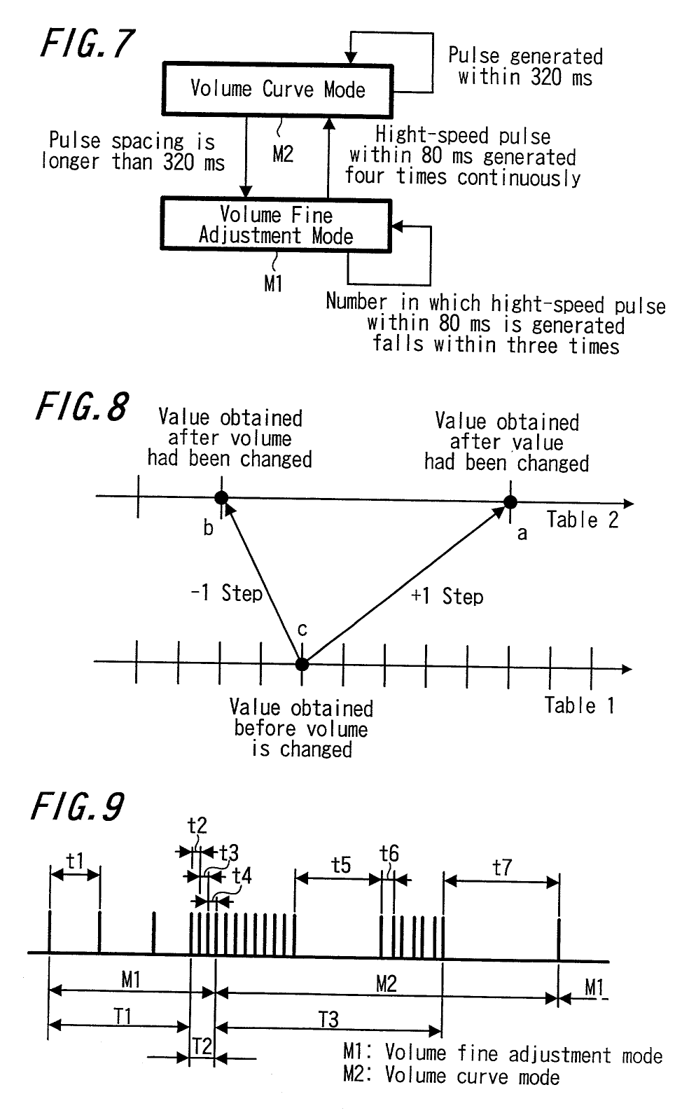

After the modes had been set in this manner, the state transition of the sound adjustment mode is presented as shown in FIG. 7. Specifically, the rotary control comprising the volume encoder starts to rotate, a volume fine adjustment mode M1 which is the first sound volume adjustment mode is set. While the volume fine adjustment mode M1 is set, even when a pulse is generated at an interval shorter than 80 ms, if the number in which a pulse is generated falls within three times, then the volume fine adjustment mode M1 is maintained. When it is detected that pulses are continuously generated four times at an interval shorter than 80 ms, the volume fine adjustment mode M1 is changed to a volume curve mode M2 which is the second sound volume mode. Once this volume curve mode M2 is set, so long as a pulse is generated at a spacing less than 320 ms, the volume curve mode M2 is maintained. Then, when the pulse spacing becomes longer than 320 ms, the volume adjustment mode is changed to the volume fine adjustment mode M1.

After the steps S16, S17 and S18 in the flowchart of FIG. 5 had been executed, when the volume adjustment mode is changed, the next processing is executed. Specifically, the changed volume value becomes a value changed by one step in the element number in the new table used in response to the rotation direction of the volume encoder, i.e., the increasing direction or the decreasing direction of the volume required when the volume adjustment mode is changed. Since the volume value is controlled as described above, sound volume can be set satisfactorily when there is no volume value in the table showing correspondence between volume values and element numbers newly set by the change of the mode. Specifically, as shown in FIG. 8, for example, under the condition that the volume value which is the volume fine adjustment mode serving as the first mode is set, when this volume value has to be changed by one step by changing the volume fine adjustment mode to the volume curve mode of the second mode, if the rotation direction is the direction in which the sound volume is increased, then a step value which becomes a closest volume value in the direction in which the sound volume is increased is selected from the present volume value in the second mode. In this case, when the volume value is the volume value of c in the table 1, for example, the changed volume value is set to a in the table 2. Under the situation in which a volume value which is the volume fine adjustment mode in the first mode is set, when the volume value has to be changed by one step by changing the volume fine adjustment mode to the volume curve mode of the second mode, if the rotation direction is the direction in which sound volume is decreased, a step value which becomes a closest volume value in the direction in which sound volume is decreased from the current volume value in the second value. In this case, when the volume value obtained before being changed is a value c in the table 1, a value b in the table 2 is set as a changed volume value. In this manner, sound volume can be changed satisfactorily when the mode is changed.

FIG. 9 shows an example of the manner in which a mode is changed in response to the pulse output by the above processing. As shown in FIG. 9, in the initial state, the volume fine adjustment mode M1 is set and each time one pulse is detected, a volume value is changed by one step each. In this volume fine adjustment mode M1, when a pulse spacing t1 is longer than 80 ms, such volume fine adjustment mode M1 is maintained. In the case of FIG. 9, during a period T1, the pulse spacing is detected as being longer than 80 ms. Next, during a period T2, when the rotary control is operated at high speed in such a manner that three continuous pulse spacings t21, t3, t4 fall within 80 ms, the volume fine adjustment mode M1 is changed to the volume curve mode M2. Once this volume curve mode M2 is set, so long as pulse spacings t5, t6 are less than 320 ms, the volume curve mode M2 is maintained. In the case of FIG. 9, during a period T3, since the spacings t5, t6 in which pulses are detected are also less than 320 ms, the volume curve mode M2 is maintained. Then, when a pulse spacing becomes longer than 320 ms, the volume curve mode M2 is returned to the volume fine adjustment mode M1.

Since the sound volume adjustment mode is set as described above, in the initial state in which a user begins to operate the rotary control, each time the rotary control is rotated 15°, the sound volume mode becomes the volume fine adjustment mode in which a volume value is increased or decreased by 1 dB each so that sound volume can be fine adjusted in response to rotation of the rotary control. When the rotary control is operated at high speed under the condition that four pulses are outputted at a spacing shorter than 80 ms in this volume fine adjustment mode, the volume fine adjustment mode is changed to the volume curve mode. Accordingly, the volume value can be changed at high speed in which the number of steps is less so that sound volume can be increased or decreased by small rotation of the rotary control. Since the volume fine adjustment mode is not changed to the volume curve mode until four pulses are outputted at a spacing shorter than 80 ms, even when a pulse is outputted at a spacing shorter than 80 ms temporarily, the volume fine adjustment mode is not changed to the volume curve mode, and hence it is possible to effectively prevent the mode from being changed erroneously.

Once this volume curve mode is set, the volume curve mode is not returned to the volume fine adjustment mode until a pulse spacing longer than 320 ms which is a relatively long time period is detected. Accordingly, the setting of mode can be prevented from becoming unstable. Specifically, when a user operates the rotary control, the user operates the rotary control with finger. In the ordinary operation, even when the user rotates the rotary control at high speed, after the user had rotated the rotary control a certain degree of angles, the user has to get fingers off the rotary control and has to again rotate the rotary control at high speed. As a results even when the rotary control is rotated at high speed, there exist the state in which a pulse spacing is extended temporarily. In the case of this embodiment, even when the user has to get fingers off the rotary control and has to again rotate the rotary control at high speed, since the condition in which the volume curve mode is returned to the volume fine adjustment mode is the condition that the pulse spacing should be longer than 320 ms, if the user gets fingers off the rotary control and starts again to rotate the rotary control at high speed during a time period less than 320 ms, the volume curve mode can be maintained and the mode in which sound volume can be adjusted at high speed can be maintained.

While the values of the pulse spacings are set to 80 mn and 320 ms by way of example as described so far, the present invention is not limited thereto and the mode can be set based on judgment of values other than these values. While FIGS. 3A, 3B, 3C show examples of correspondences of the step values and the volume values of the respective modes by way of example, the present invention is not limited thereto and other values may be set. The curve characteristics of the volume curve mode also may be changed to other characteristics. For example, the minimum level may be changed to the maximum level by lesser steps

In the above embodiment, the curve characteristics of the volume curve mode need not be prepared as the tables but the number of steps may be calculated by equations showing curve characteristics.

Further, while there is provided one kind of volume curve mode as described above, the present invention is not limited thereto and there may be prepared a plurality of volume curve modes. In addition, a range in which the mode is selected by the pulse spacing may be subdivided into small ranges so that the volume curve mode may be fine changed in response to the rotation speed of the rotary control. Further, in the volume fine adjustment mode, the tables shown in FIGS. 3A, 3B, 3C need not be prepared but a new set value may be calculated by adding or subtracting a predetermined increased amount or a predetermined decreased amount to or from the set value which is not yet changed.

While the present invention is applied to the audio device in which the amplifying apparatus called the receiver apparatus and the tuner are integrated as one body as described above, the present invention is not limited thereto and can be applied to volume control of other audio devices. The above processing may be applied to sound volume adjustment processing in other devices having audio output functions, such as video devices. Further, the present invention may be applied to a rotary operating means for tuning frequencies of a tuner of a receiver apparatus. In this case, when frequencies are tuned to a broadcasting station whose frequency is distant, a frequency can be approached near a new desired channel-selection frequency at a coarse frequency step by rotating the rotary control so as to generate pulses at a short spacing. Thereafter, a frequency can be fine adjusted so as to generate pulses at a long spacing by slowly turning the rotary control.

According to the present invention, depending upon the operation speed of the rotary type operating means, the sound volume adjustment mode in which sound volume can be fine adjusted by the number of fine steps and the sound volume adjustment mode in which sound volume can rapidly be adjusted by lesser steps can be switched and used so that rapid operability becomes compatible with operability which can be fine adjusted In particular, since the sound volume adjustment mode is automatically switched based on the operation speed of the rotary type operation means which adjusts sound volume, operations for switching the mode are not required separately and hence satisfactory operability can be maintained.

In this case, the control means adjusts the output sound volume in the fist sound volume adjustment mode in which sound volume can be fine adjusted when the rotation detecting means begins to detect rotation of the rotary control and changes the first sound volume adjustment mode to the second sound volume adjustment mode after the second rotating state had been detected the first time or longer. Accordingly, since the first time is set satisfactorily, when the first sound volume adjustment mode is set, even though the rotation speed is temporarily decreased, the first sound volume adjustment mode can be maintained. Hence, the mode can be prevented from being switched by mistake so that sound volume can be prevented from being changed considerably.

Further, the control means sets the second sound volume adjustment mode and maintains the second sound volume adjustment mode when the detection of the second rotation state by the rotation detecting means does not fall within the second time. When the second rotation state is not detected over the second time, the control means changes the second sound volume adjustment mode to the first sound volume adjustment mode. Since the second time is set satisfactorily, when the second sound volume adjustment mode, for example, is set, even though the user does not temporarily operate the operation means in order to pass the operation means from the present fingers to other fingers, the second sound volume adjustment mode can be maintained, and hence rapid operability can be maintained.

Further, when the first sound volume adjustment mode is changed to the second sound volume adjustment mode, the control means sets sound volume of most approximate value in the rotation direction detected by the rotation detecting means, whereby the sound volume setting situation can be obtained as the most suitable state corresponding to the operation situation obtained at that time.

Furthermore, since the rotary type operation means is constructed as the pulse encoder for outputting a pulse each time the rotary type operation means is rotated a predetermined angle and the rotation detecting means detects the rotation state from the period of the pulse, rotation speed detection processing can be executed simply and reliably by using the pulse encoder for generating pulses and the pulse detecting circuit for detecting the pulse outputted from the pulse encoder.

Having described a preferred embodiment of the invention with reference to the accompanying drawings, it is to be understood that the present invention is not limited to that precise embodiment and that various changes and modifications could be effected therein by one skilled in the art without departing from the spirit or scope of the invention as defined in the appended claims.

What is claimed is:

1. An input apparatus for outputting a physical amount based on rotation operation done by a user, comprising:
rotary operation means rotated by operation of a user and outputting a rotation signal each time it is rotated a predetermined rotation angle;
speed detecting means for detecting a rotation speed of said rotary operation means based on a rotation signal outputted from said rotary operation means; and
control means for changing a changing amount of an outputted physical amount based on said detected rotation speed.

2. An input apparatus according to claim 1, wherein said control means changes said physical amount by a first changing amount when a rotation speed detected by said speed detecting means is lower than a predetermined speed.

3. An input apparatus according to claim 2, wherein said first changing amount is a maximum resolution of a physical amount outputted from said input apparatus.

4. An input apparatus according to claim 2, wherein said physical amount outputted from said input apparatus is changed by a second changing amount when a rotation speed detected by said speed detecting means is higher than a predetermined speed.

5. An input apparatus according to claim 4, wherein said second changing amount is larger than said first changing amount.

6. An input apparatus according to claim 4, further comprising memory means for storing therein management information for associating an outputted physical amount and said second changing amount with each other and wherein said changing amount is calculated based on management information stored in said memory means when said rotation speed is higher than a predetermined speed.

7. An input apparatus according to claim 4, wherein said physical amount is changed by said second changing amount after said rotary operation means had outputted a rotation signal of a predetermined amount.

8. An input apparatus according to claim 4, wherein said changing amount is held at said second changing amount if a time period in which a user is not operating said rotary operation means reaches a predetermined period when said physical amount is being changed by said second changing amount.

9. An input apparatus according to claim 4, wherein outputted physical amounts changed by said second changing amount become values which are spaced apart from each other.

10. An input apparatus according to claim 9, wherein a physical amount close to the physical amount outputted based on said second changing amount is selected and outputted when said changing amount changes from said first changing amount to said second changing amount.

11. An input apparatus according to claim 1, wherein said physical amount is changed by said first changing amount when a user rotates said rotary operation means if a user does not rotate said rotary operation means longer than a predetermined time.

12. An input apparatus according to claim 1, further comprising rotation direction detecting means for detecting rotation direction of said rotary operation means and wherein said physical amount is changed by said first changing amount when rotation direction detected by said rotation direction detecting means is changed.

13. An input apparatus according to claim 1, wherein said rotary operation means is a rotary encoder whose rotation angle is not restricted.

14. A reproducing apparatus for adjusting reproduction volume by switching a coarse adjustment mode and a fine adjustment mode based on rotation of a control operated by a user and whose rotation angle is not restricted, comprising:
reproducing means for reproducing an audio signal;
attenuating means for adjusting reproduction volume of said audio signal;
amplifying means for amplifying an audio signal whose level was adjusted by said attenuating means;
rotation detecting means coupled to a control operated by a user and which outputs a predetermined rotation signal each time it is rotated a predetermined rotation angle;
speed detecting means for detecting rotation speed of said control based on a rotation signal outputted from said rotation detecting means;
direction detecting means for detecting rotation direction of said control based on a rotation signal outputted from said rotation detecting means;
adjustment amount output means for outputting a first adjustment amount for changing said reproduction volume by said first adjustment amount in said fine adjustment mode;
memory means for storing therein control information for changing said reproduction volume by a second adjustment amount in said coarse adjustment mode; and
control means for controlling said attenuating means such that said attenuating means increases or decreases said reproduction volume in said fine adjustment mode based on said first adjustment amount outputted from said adjustment amount output means and detected result of said direction detecting means when it is detected by said speed detecting means that said control is operated at first speed and controlling said attenuating means such that said attenuating means increases or decreases said reproduction volume in said coarse adjustment mode based on said second adjustment amount controlled by control information stored in said memory means and detected result of said direction detecting means when it is detected by said speed detecting means that said control is operated at second speed.

15. A reproducing apparatus according to claim 14, further comprising clock means for calculating a time and wherein said control means further controls said attenuating means such that an attenuation amount of said attenuating means increases or decreases in said coarse adjustment mode based on a detected result of said direction detecting means and said first adjustment amount outputted from said adjustment amount output means when it is detected by calculated result of said clock means that said control is operated by a user after said control had not been operated over a predetermined time.

16. A reproducing apparatus according to claim 14, further comprising clock means for calculating time and wherein said control means continues said coarse adjustment mode if it is determined based on calculated result of said clock means that lowered rotation speed detected by said speed detecting means falls within a predetermined time when an attenuated amount is adjusted in said coarse adjustment mode.

17. A reproducing apparatus according to claim 14, wherein said control means moves to said coarse adjustment mode if it is detected that said control is rotated at said second speed continuously until detection of said rotation signal continues more than a predetermined amount.

18. A sound volume adjusting method for adjusting reproduction sound volume by switching a coarse adjustment mode and a fine adjustment mode based on rotation of a control operated by a user and whose rotation angle is not restricted, comprising the steps of:
detecting rotation speed and rotation direction of said control;
comparing said rotation speed with predetermined speed;
adjusting said reproduction sound volume based on a first adjustment amount and said detected rotation direction in a fine adjustment mode if it is determined based on said comparison that rotation of said control is lower than a predetermined speed; and
adjusting said reproduction sound volume based on a second adjustment amount and said detected rotation direction in a coarse adjustment mode if it is determined by said comparison that rotation of said control exceeds predetermined speed.

19. A sound volume adjusting method according to claim 18, comprising the steps of:
calculating a time during which said control is not operated; and
setting an adjustment mode of said reproduction sound volume to said fine adjustment mode if said calculated result exceeds a predetermined time.

20. A sound volume adjusting method according to claim 19, wherein said coarse adjustment mode continues if it is determined that a calculated time during which said control is not operated is less than a predetermined time when sound volume is being adjusted in said coarse adjustment mode.
